(19) United States
(12) Patent Application Publication
(10) Pub. No.: US 2010/0206368 A1
(43) Pub. Date: Aug. 19, 2010

(54) THIN FILM SOLAR CELL AND MANUFACTURING METHOD FOR THE SAME

(76) Inventors: Taeyoun Kim, Seoul (KR); Wonseo Park, Goyang-si (KR); Jeongwoo Lee, Paju-si (KR); Seongkee Park, Goyang-si (KR); Kyungjin Shim, Cheongju-si (KR)

Correspondence Address: BIRCH STEWART KOLASCH & BIRCH, PO BOX 747, FALLS CHURCH, VA, 22040-0747, US

(21) Appl. No.: 12/630,810

(22) Filed: Dec. 3, 2009

(30) Foreign Application Priority Data
Feb. 16, 2009 (KR) 10-2009-0012342

(51) Int. Cl. H01L 31/0224; H01L 31/18

(52) U.S. Cl. 136/255; 136/256; 438/57; 257/E31.124

(57) ABSTRACT

Thin film solar cell and a manufacturing method for the same are disclosed. Thin film solar cell according to one embodiment of this document comprises a substrate, a first electrode positioned on the substrate including a plurality of conductive particles and having unevenness on the surface thereof, an absorption layer positioned on the first electrode, and a second electrode positioned on the absorption layer.

This application claims the benefit of Korean Patent Application No. 10-2009-0012342 filed on February 16, which is hereby incorporated by reference.

### BACKGROUND

1. Field

This document relates to thin file solar cell and a manufacturing method for the same.

2. Description of the Related Art

Various researches are being conducted in search for a substitute for fossil fuels to resolve the imminent energy crisis. In particular, to substitute for oil resources to be exhausted in a few decades from now, researchers are focusing on how to utilize natural energy resources such as wind, atomic, and solar energy.

Different from the other potential substitutes, solar cell is eco-friendly, making use of unlimited solar energy. Solar cell, therefore, has been studied a lot over the past few decades since the development of Se solar cell at 1983. Commercial solar cell of today utilizing single crystal bulk silicon is not widely used because of high cost for manufacturing and installation.

To resolve the cost problem, thin film solar cell is studied actively. Particularly, thin film solar cell that makes use of amorphous silicon (a-Si:H) is obtaining great attention as a technology which can fabricate large-area solar cell at a low cost.

In general, thin file solar cell can be made of a multilayer structure that a first electrode, an absorption layer, and a second electrode are stacked on a first substrate. To improve the efficiency of thin film solar cell, a texturing process is carried out to form a large unevenness on the surface of the first electrode. Traditional texturing process employs a chemical etching method that makes use of acid/base solution.

While the manufacturing process of solar cell is carried out mostly in a vacuum state, since the texturing process that utilizes the aforementioned chemical etching method employs acid/base solution, the vacuum process is damaged and to return to the vacuum state, tact time of the process is lengthened.

Also, etching solution has to be changed according to the material of a first electrode and it is not easy to control the shape of unevenness arbitrarily. Further, surface of the first electrode can be damaged, leading to the increase of resistance value. Still another problem is disposal of acid/base etching solution waste.

### SUMMARY

This document has been made in an effort to provide thin film solar cell and a manufacturing method for the same, whereby unevenness in a first electrode of solar cell can be easily formed with reduced manufacturing time and degradation of electrical characteristics thereof can be prevented.

Thin film solar cell according to one embodiment of this document comprises a substrate; a first electrode positioned on the substrate, including a plurality of conductive particles and having unevenness formed on the surface of the first electrode; an absorption layer positioned on the first electrode; and a second electrode positioned on the absorption layer.

### BRIEF DESCRIPTION OF THE DRAWINGS

The accompany drawings, which are included to provide a further understanding of the invention and are incorporated on and constitute a part of this specification illustrate embodiments of the invention and together with the description serve to explain the principles of the invention.

FIG. 1 illustrates thin film solar cell according to one embodiment of this document;

FIGS. 2A to 2G illustrate respective processes of manufacturing thin film solar cell according to one embodiment of this document; and

FIGS. 3A and 3B illustrate SEM pictures measuring the surface of a first electrode of thin film solar cell according to embodiments of this document.

### DETAILED DESCRIPTION OF PREFERRED EMBODIMENTS

Reference will now be made in detail embodiments of the invention examples of which are illustrated in the accompanying drawings.

Thin film solar cell according to one embodiment of this document comprises a substrate; a first electrode positioned on the substrate, including a plurality of conductive particles and having unevenness formed on the surface the first electrode; an absorption layer positioned on the first electrode; and a second electrode positioned on the absorption layer.

The plurality of conductive particles can include more than one selected from a group consisting of zinc oxide (ZnO), tin oxide (SnO), cardmium oxide (Cd₂0₃), and indium tin oxide (ITO).

The plurality of conductive particles can be doped with one selected from a group consisting of gallium (Ga), aluminum (Al), boron (B), fluorine (F), and tin (Sn).

Particle size of the plurality of conductive particles can substantially range from 0.01 to 0.7 μm.

A method for manufacturing thin film solar cell according to one embodiment of this document comprises forming a first electrode having unevenness on the surface thereof, the first electrode including a plurality of conductive particles on a substrate; forming an absorption layer on the first electrode; and a second electrode on the absorption layer.

The plurality of conductive particles can be coated with solution.

The plurality of conductive particles can be formed by any one of spin coating, dip coating, or printing method.

The forming of the first electrode comprises spreading a solution including the plurality of conductive particles on the substrate, removing the solution by heating the substrate, and depositing transparent conductive material on the substrate where the plurality of conductive particles are formed.

Particle size of the plurality of conductive particles can substantially range from 0.01 to 0.7 μm.

The plurality of conductive particles can be doped with any one selected from a group consisting of gallium (Ga), aluminum (Al), boron (B), fluorine (F), and tin (Sn).

In what follows, with reference to necessary drawings, embodiments of this document are described.

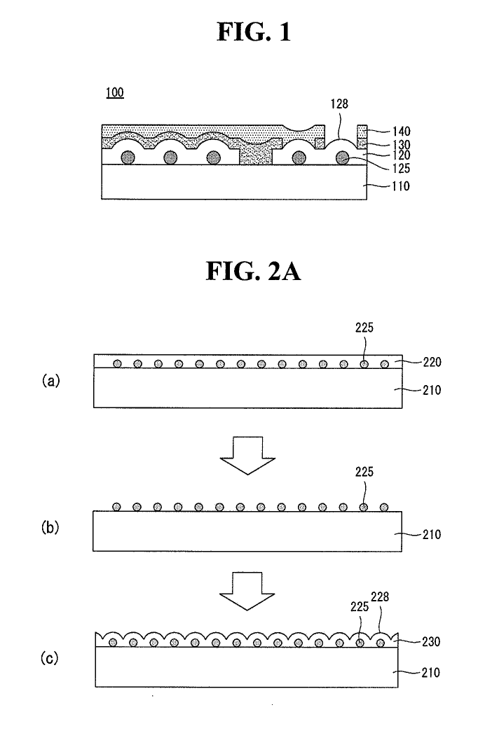

FIG. 1 illustrates thin film solar cell according to one embodiment of This document

With reference to FIG. 1, thin film solar cell 100 according to one embodiment of this document comprises a substrate 110; a first electrode 120 positioned on the substrate 110, including a plurality of conductive particles 125, and having unevenness 128 formed on the surface of the first electrode 120; an absorption layer 130 positioned on the first electrode 120, and a second electrode 140 positioned on the absorption layer 130.

The substrate 110 can use glass or transparent resin film. The glass can be glass panel, ingredients of which are silicon oxide (SiO₂), sodium oxide (Na₂O), and calcium oxide (CaO) with superior transparency and non-conductivity.

The first electrode 120 can be composed of transparent conductive oxide or metal. The transparent conductive oxide can be made by any one selected from a group consisting of zinc oxide (ZnO), tin oxide (SnO), cadmium oxide (Cd₂O₃), and indium tin oxide (ITO), preferably indium tin oxide (ITO). As for the metal, silver (Ag) or aluminum (Al) can be used.

The first electrode 120 can be single layer formed by transparent conductive oxide or metal, but is not limited thereto and can be multilayer of two or more than two layers formed by transparent conductive oxide/metal.

Meanwhile, the first electrode 120 can include a plurality of conductive particles 125. The plurality of particles 125 can enlarge the surface area of the first electrode 120 by facilitating unevenness 128 to be formed on the surface of the first electrode 120.

A plurality of conductive particles 125 can be formed by any one selected from a group consisting of zinc oxide (ZnO), tin oxide (SnO), cadmium oxide (Cd₂O₃), and indium tin oxide (ITO).

Also, the plurality of conductive particles 125 can be doped by any one selected from a group consisting of gallium (Ga), Aluminum (Al), boron (B), fluorine (F), and tin (Sn).

Particle size of the plurality of conductive particles 125 can substantially range from 0.01 to 0.7 μm. If the size of a conductive particle 125 is more than 0.01 μm, unevenness can be formed in the first electrode 120, enlarging the surface area of the first electrode 120. On the other hand, if the size of a conductive particle 125 is less than 0.7 μm, one can also have an advantageous effect that thickness of the first electrode 120 can be prevented from being thickened.

A plurality of unevenness 128 can be formed on the surface of the first electrode 120 due to a plurality of conductive particles 125. The unevenness 128 enlarges the surface area of the first electrode 120 and thus causes dispersion of light incident on the first electrode 120, thereby giving an advantageous effect of lengthening light path.

Meanwhile, the absorption layer 130 can be formed by amorphous silicon, CdTe, or CIGS (CulnGaSe₂) and can have a pin structure. To give an example with an assumption that the absorption layer 130 is amorphous silicon, the pin structure can be formed by p+ type amorphous silicon layer/i (intrinsic)-type amorphous silicon layer/n+ amorphous silicon layer.

In the above assumption, silicon thin film layer in the pin structure absorbs incident sunlight and electron-hole pairs are generated. In the pin structure, electrons and holes generated previously by built-in potential established by p-n junction move respectively to n type and p type semiconductor for subsequent utilization.

Although the absorption layer 130 is illustrated as a single layer in the present embodiment, the absorption layer 130 can be a structure composed of p+ type amorphous silicon layer/i (intrinsic)-type amorphous silicon layer/n+ amorphous silicon layer.

In the same way as the first electrode 120, the second electrode 140 can be composed of transparent conductive oxide or metal. The transparent conductive oxide can be made by indium tin oxide (ITO), tin oxide (SnO), or zinc oxide (ZnO), preferably indium tin oxide (ITO). As for the metal, silver (Ag) or aluminum (Al) can be used.

A second electrode 140 can be single layer formed by transparent conductive oxide or metal, but is not limited thereto and can be multilayer of two or more than two layers formed by transparent conductive oxide/metal.

In what follows, a manufacturing method of thin film solar cell according to one embodiment of this document is described.

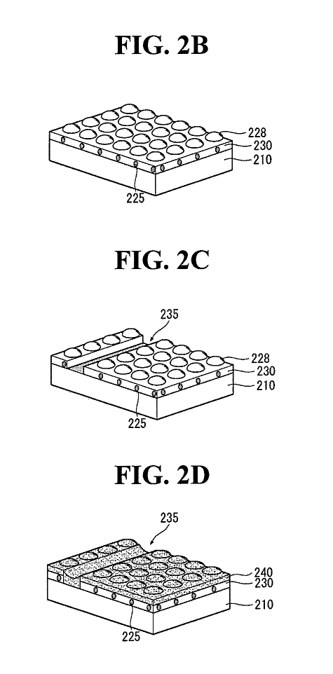

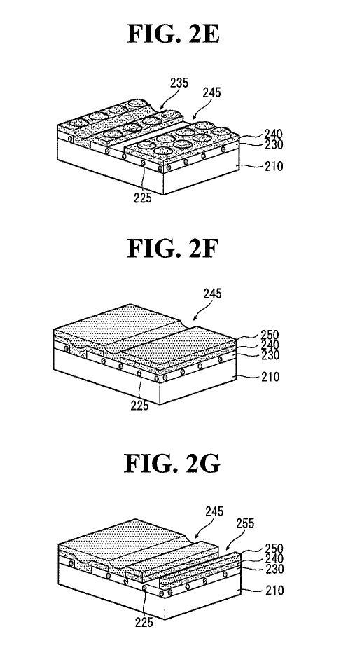

FIGS. 2A to 2G illustrate the respective processes of manufacturing thin film solar cell according to one embodiment of this document.

A method for manufacturing thin film solar cell according to one embodiment of this document comprises forming a first electrode having unevenness on the surface thereof, the first electrode including a plurality of conductive particles on a substrate, forming an absorption layer on the first electrode; and a second electrode on the absorption layer.

First, forming a first electrode 230 including a plurality of conductive particles 225 on a substrate 210 is described in the following with reference to FIG. 2A.

(A) A substrate 210 is coated with solution 220 including a plurality of conductive particles 225.

At this time, the substrate 210 can use glass or transparent resin film. The glass can be flat glass panel, ingredients of which are silicon oxide (SiO₂), sodium oxide (Na₂O), and calcium oxide (CaO) with superior transparency and non-conductivity.

The solution 220 can be anything such as methanol, ethanol, or alcohol if it can disperse the plurality of conductive particles 225.

A coating method by using the solution 220 can be any one of spin coating, dip coating, or printing method

Meanwhile, the plurality of conductive particles 225 can be formed by any one selected from a group consisting of zinc oxide (ZnO), tin oxide (SnO), cadmium oxide (Cd₂O₃), and indium tin oxide (ITO).

Also, the plurality of conductive particles 225 can be doped with any one selected from a group consisting of gallium (Ga), aluminum (Al), boron (B), fluorine (F), and tin (Sn). In this case, doping density can range from 3 to 7 percent.

Particle size of the plurality of conductive particles 225 can substantially range from 0.01 to 0.7 μm. If the size of a conductive particle 225 is more than 0.01 μm, unevenness can be formed afterwards in the first electrode 230, enlarging the surface area of the first electrode 230. On the other hand, if the size of a conductive particle 225 is less than 0.7 μm, one can also have an advantageous effect that thickness of the first electrode 230 can be prevented from being thickened.

Next, (B) solution 220 is removed by heating a substrate 210 coated with the solution 220 including the plurality of conductive particles 225.

The solution 220 can be removed by heating for 1 to 10 minutes in the oven at 150° C.

Subsequently, (C) a first electrode 230 including a plurality of conductive particles 225 is formed by deposition of transparent conductive material on a substrate 210 where solution has been removed.

On the substrate 210 where solution has been removed through the previous heating process, only multiple conductive particles 225 remain. Therefore, if transparent conductive material is deposited on the substrate 210 where a plurality of conductive particles 225 are formed, a first electrode 230 having unevenness 228 on the surface thereof due to the plurality of conductive particles 225 can be formed.

The first electrode 230 can be composed of transparent conductive oxide or metal. The transparent conductive oxide can be made by any one selected from a group consisting of zinc oxide (ZnO), tin oxide (SnO), cadmium oxide (Cd₂O₃), and indium tin oxide (ITO), preferably indium tin oxide (ITO). As for the metal, silver (Ag) or aluminum (Al) can be used.

A first electrode 120 can be single layer formed by transparent conductive oxide or metal, but is not limited thereto and can be multilayer of two or more than two layers formed by transparent conductive oxide/metal.

Also, a first electrode 230 can be formed by chemical vapor deposition (CVD), physical vapor deposition (PVD), or an electron beam (E-beam) method.

Therefore, as shown in FIG. 2B, a first electrode 230 can be formed, the first electrode 230 having unevenness 228 formed on the surface thereof and a plurality of conductive particles 225 formed on the substrate 210.

As described above, by forming unevenness on the surface of a first electrode through a plurality of conductive particles, the traditional process of forming unevenness on a first electrode by using acid/base etching solution can be replaced.

Accordingly, size of unevenness of a first electrode can be easily adjusted by adjusting the size of a conductive particle and degradation of electrical characteristics due to damage to the first electrode can be prevented. Also, process tact time can be reduced since vacuum process is maintained.

Next, with reference to FIG. 2C, the first electrode 230 undergoes patterning.

At this time, patterning a first electrode 230 can use a photo-resist method, a sand blast method, or a laser scribing method. In this case, the first electrode 230 can be separated by a first patterning line 235.

Subsequently, with reference to FIG. 2D, an absorption layer 240 is formed on the first electrode 230 where the patterning process has been completed.

The absorption layer 240 can be formed by amorphous silicon, CdTe, or CIGS (CuInGaSe₂) and can have a pin structure. To give an example with an assumption that the absorption layer 240 is amorphous silicon, the pin structure can be formed by p+ type amorphous silicon layer/i (intrinsic)-type amorphous silicon layer/n+ amorphous silicon layer.

In the above assumption, silicon thin film layer in the pin structure absorbs incident sunlight and electron-hole pairs are generated. In the pin structure, electrons and holes generated previously by built-in potential established by p-n junction move respectively to n type and p type semiconductor for subsequent utilization.

Although the absorption layer 240 is illustrated as a single layer in the present embodiment, the absorption layer 240 can be a structure composed of p+ type amorphous silicon layer/i (intrinsic)-type amorphous silicon layer/n+ amorphous silicon layer.

At this time, the absorption layer 240 can be deposited by plasma enhanced chemical vapor deposition (PECVD) method.

Next, with reference to FIG. 2E, the absorption layer 240 undergoes patterning.

At this time, a first patterning line 235 patterned after the first electrode 230 and an absorption layer 240 of a separated area are patterned. In this case, a patterning method for the absorption layer 240 can use a photo-resist method, a sand blast method, or a laser scribing method.

Therefore, the absorption layer 240 can be separated by a second patterning line 245.

Next, with reference to FIG. 2F, a second electrode 250 is formed on a substrate 210 where patterning process of the absorption layer 240 has been completed.

In the same way as the first electrode 230, a second electrode 250 can be composed of transparent conductive oxide or metal. The transparent conductive oxide can be made by indium tin oxide (ITO), tin oxide (SnO), or zinc oxide (ZnO), preferably indium tin oxide (ITO). As for the metal, silver (Ag) or aluminum (Al) can be used.

A second electrode 250 can be single layer formed by transparent conductive oxide or metal, but is not limited thereto and can be multilayer of two or more than two layers formed by transparent conductive oxide/metal.

At this time, in the same way as the first electrode 230, a second electrode 250 can be formed by chemical vapor deposition (CVD), physical vapor deposition (PVD), or an electron beam (E-beam) method.

Finally, with reference to FIG. 2G, for electrical insulation, an absorption layer 240 and a second electrode 250 formed on the substrate 210 undergo patterning.

At this time, by patterning the aforementioned first patterning line 235, a second patterning line 245, and a separated area, electrical insulation can be accomplished by a third patterning line 255.

Accordingly, as described above, thin film solar cell according to one embodiment of this document can be manufactured.

As described above, by forming unevenness on the surface of a first electrode through a plurality of conductive particles, the traditional process of forming unevenness on a first electrode by using acid/base etching solution can be replaced.

Accordingly, size of unevenness of a first electrode can be easily adjusted by adjusting the size of a conductive particle and degradation of electrical characteristics due to the damage to the first electrode can be prevented. Also, process tact time can be reduced since vacuum process is maintained.

Hereinafter, preferred embodiments of this document will be described. The embodiments in the following are provided for the illustration purpose only and thus, this document is not limited to the following embodiments.

### Embodiment 1

A glass substrate is coated with solution where gallium-doped zinc oxide (ZnO) particles with a size of 0.7 μm are dissolved. The glass substrate undergoes heating process for five minutes in an oven at 150° C., by which the solution is removed. Subsequently, a first electrode is formed by depositing zinc oxide (ZnO) on the glass substrate with a thickness of 0.4 μm by using a sputtering method.

### Embodiment 2

A glass substrate is coated with solution where gallium-doped zinc oxide (ZnO) particles with a size of 0.4 μm are dissolved. The glass substrate undergoes heating process for five minutes in an oven at 150° C., by which the solution is removed. Subsequently, a first electrode is formed by depositing zinc oxide (ZnO) on the glass substrate with a thickness of 0.4 μm by using a sputtering method.

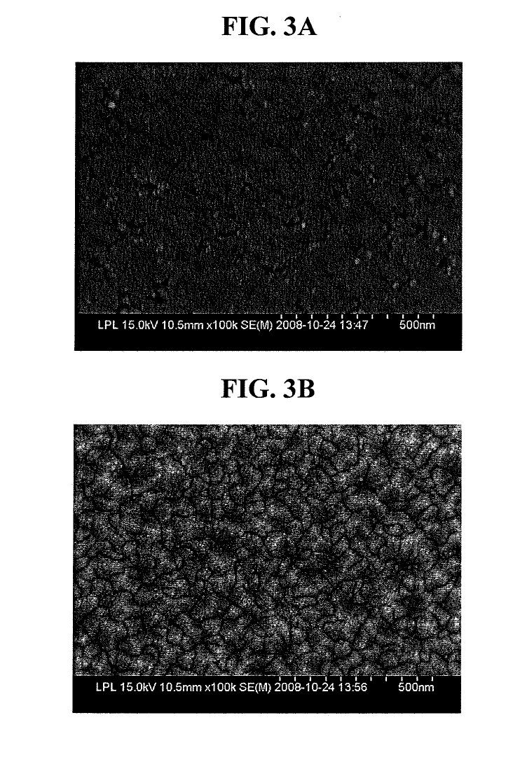

Table 1 shows measured sheet resistance and transmittance of a first electrode manufactured according to the first and second embodiment. The surface of the first electrode has been measured by SEM; FIGS. 3A and 3B illustrate the measurement result.

TABLE 1

| | Sheet resistance (Ω/sq) | Transmission (%) |
|---|---|---|
| Embodiment 1 | 35 | 93 |
| Embodiment 2 | 30 | 91 |

According to the Table 1 and FIGS. 3A and 3B, it can be noticed that both the sheet resistance and transmittance of a first electrode manufactured according to the first and second embodiment satisfy the criteria for mass production.

As described above, by forming unevenness on the surface of a first electrode through a plurality of conductive particles, the traditional process of forming unevenness on a first electrode by using acid/base etching solution can be replaced.

Accordingly, size of unevenness of a first electrode can be easily adjusted by adjusting the size of a conductive particle and degradation of electrical characteristics due to the damage to the first electrode can be prevented. Also, process tact time can be reduced since vacuum process is maintained.

The foregoing embodiments and advantages are merely exemplary and are not to be construed as limiting this document. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

What is claimed is:

1. Thin film solar cell comprising:
a substrate;
a first electrode positioned on the substrate including a plurality of conductive particles and having unevenness on the surface thereof;
an absorption layer positioned on the first electrode; and
a second electrode positioned on the absorption layer.

2. The thin film solar cell of claim 1, wherein the plurality of conductive particles include more than one selected from a group consisting of zinc oxide (ZnO), tin oxide (SnO), cardmium oxide (Cd₂O₃), and indium tin oxide (ITO).

3. The thin film solar cell of claim 2, wherein the plurality of conductive particles are doped with one selected from a group consisting of gallium (Ga), aluminum (Al), boron (B), fluorine (F), and tin (Sn).

4. The thin film solar cell of claim 1, wherein particle size of the plurality of conductive particles substantially ranges from 0.01 to 0.7 μm.

5. A method for manufacturing thin film solar cell comprising:
forming a first electrode having unevenness on the surface thereof, the first electrode including a plurality of conductive particles on a substrate;
forming an absorption layer on the first electrode; and
forming a second electrode on the absorption layer.

6. The method of claim 5, wherein the plurality of conductive particles are coated with solution.

7. The method of claim 5, wherein the plurality of conductive particles are formed by any one of spin coating, dip coating, or printing method.

8. The method of claim 5, wherein the forming of the first electrode comprises spreading a solution including the plurality of conductive particles on the substrate; removing the solution by heating the substrate; and depositing transparent conductive material on the substrate where the plurality of conductive particles are formed.

9. The method of claim 5, wherein particle size of the plurality of conductive particles can substantially range from 0.01 to 0.7 μm.

10. The method of claim 5, wherein the plurality of conductive particles are doped with any one selected from a group consisting of gallium (Ga), aluminum (Al), boron (B), fluorine (F), and tin (Sn).
